(19) United States
(12) Patent Application Publication
(10) Pub. No.: US 2012/0167943 A1
(43) Pub. Date: Jul. 5, 2012

(54) Unwindable Flat Solar Generator

(75) Inventors: Laurent BLANCHARD, Mouans-Sartoux (FR); Julien DUCARNE, Cannes (FR); Freddy GEYER, Mandelieu (FR); Yannick BAUDASSE, Grasse (FR)

(73) Assignee: THALES, Neuilly-sur-Seine (FR)

(21) Appl. No.: 13/336,878

(22) Filed: Dec. 23, 2011

(30) Foreign Application Priority Data
Dec. 30, 2010 (FR) 10 05184

(51) Int. Cl. H01L 31/045; B65H 16/00

(52) U.S. Cl. 136/245; 242/550

(57) ABSTRACT

A solar generator deployment device includes an assembly comprising a plurality of tape-springs supporting a windable membrane on a face of which is arranged a plurality of elements capable of converting the solar energy into electrical energy. The tape-springs and membrane are co-wound around a unique radius of curvature equal to the natural radius of curvature of folding of the tape-spring in the wound state. The tape-springs are substantially parallel and interlinked by transversal braces ensuring the rigidity of the bearing structure.

### CROSS-REFERENCE TO RELATED APPLICATION

This application claims priority to foreign French patent application No. FR 1005184, filed on Dec. 30, 2010, the disclosure of which is incorporated by reference in its entirety.

### FIELD OF THE INVENTION

The field of the invention is that of structures that are deployable in space that can advantageously be used for the deployment of solar generators.

### BACKGROUND

Tape-springs are known as such in the space domain as being tapes capable of changing from the wound state to the unwound state essentially by virtue of their own elastic energy; in the unwound state, the known tape-springs generally exhibit a rigidity which is capable of maintaining them in that state.

The conventional tape-springs, generally metallic, therefore have a natural tendency to unfold to return to their stable state. If they are forced to be folded back, they have a tendency to do so over a radius equal to that of their transversal radius of curvature. A weak external force is therefore needed to keep them wound in this form. If this force is abruptly eliminated, the unfolding can be violent and uncontrolled, which means that the whole tape-spring may have a tendency to straighten out simultaneously, over its entire length. Conventional tape-springs may thus present difficulties when it comes to controlling their unfolding.

Conventional tape-springs made of composite material have also been developed. The latter have properties that are for the most part similar to those of the conventional metal tape-springs, but offer the advantage of making it possible, to a certain extent, to control their own winding radius. They also offer the advantage of a high rigidity/weight ratio and a low expansion coefficient.

The applicant has already demonstrated that it is possible to combine a conventional tape-spring with a layer of thermoplastic material. This invention was the subject of the patent application FR 0803986. The conventional tape-spring comprising a layer of thermoplastic material can be wound by force, heated then cooled so that the thermoplastic sets the tape-spring in the wound state, which then becomes the stable state. By local heating, it is possible to progressively unwind the assembly. Alternatively, it is possible to use, instead of the thermoplastic material, a thermosetting material or, more generally, a material exhibiting a strong rigidity variation on crossing a temperature threshold.

Finally, by construction, it is possible to render a composite tape-spring bistable. Studies have been published on this issue, such as, notably, “Carbon Fibre Reinforced Plastic Tape Springs”, J. C. H. Yee et al, AIAA 2004-1819, and “Analytical models for bistable cylindrical shells”, S. D. Guest et al.

The noteworthy property of the bistable tape-springs lies in the fact that they are mechanically stable both in the unwound state and in the wound state. The more stable state does, however, remain the unwound state. The bistable tape-springs are wound via a generally significant force. They remain stable in the wound state around their natural radius of curvature, without external force. All that is needed is to unfold one end thereof, with a force of low intensity, exerted by a motor-drive system for example, to trigger the unwinding. The unwinding can be very fast, but remains progressive from the initial unwinding point.

The general issue that the invention addresses lies in the deployment of large size solar generators and the consequent issue of bulk in the nose cone of the launch vehicles.

There are numerous technological possibilities for deploying huge solar generators in space, such as those described in the patents U.S. Pat. No. 6,555,740, in which the bearing structure and the membrane supporting the photovoltaic cells of solar generators are deployed separately, or the patent U.S. Pat. No. 6,543,725, in which the bearing structure is folded (and not wound).

The present invention constitutes a technological alternative to these known solutions, offering the advantage of being less bulky, and of making it possible to more finely control the deployment of large size solar generators.

The state of the art also includes a device for the deployment of panels stored folded accordion-fashion and that can be deployed using a polymerized and inflatable composite tube. However, this type of device can be used only once, because the polymerization is irreversible. This poses a problem for demonstrating and validating the complete deployment on the ground before being sent into space.

### SUMMARY OF THE INVENTION

One aim of the invention is notably to overcome the abovementioned drawbacks. To ensure the deployment of large size solar generators, it proposes the use of a structure comprising parallel tape-springs, to which is fixed a membrane which is flexible, semirigid, or made up of flexible and rigid elements such as thin, flat braces linked flexibly together, said membrane having a face on which are arranged a plurality of elements capable of converting the solar energy into electrical energy.

More precisely, the subject of the invention is a solar generator deployment device comprising an assembly comprising a plurality of tape-springs supporting a windable membrane on a face of which is arranged a plurality of elements capable of converting the solar energy into electrical energy, characterized in that, in the wound state, said tape-springs and said membrane are co-wound around a unique radius of curvature equal to the natural radius of curvature of folding of the tape-spring and in that said tape-springs are substantially parallel and interlinked by transversal braces ensuring the rigidity of the bearing structure.

Advantageously, said assembly comprises:
at least one main tape-spring, the function of which is to maintain the membrane in the wound position before deployment and to regulate the deployment using actuation means, and,
at least one conventional secondary tape-spring, made of metal or of composite material, the function of which is to provide motorization for the deployment of the membrane by its natural tendency to unfold.

Advantageously, the at least one main tape-spring (1) combines a composite material and a layer of a material exhibiting a strong rigidity variation on crossing a temperature threshold and the actuation means are thermal.

Advantageously, the at least one main tape-spring combines a composite material and a thermoplastic layer and the actuation means are thermal.

Advantageously, the at least one main tape-spring is of bistable type and the actuation means are triggering means.

Advantageously, the at least one main tape-spring is of bistable type and also comprises a layer of a material exhibiting a strong rigidity variation on crossing a temperature threshold and the actuation means are thermal. Advantageously, said assembly and said membrane can be co-wound around a mandrill with a radius preferentially greater than or equal to the natural radius of curvature of said tape-spring.

Advantageously, said membrane may be flexible.

Advantageously, said membrane may be made of flexible and rigid elements.

Advantageously, said flexible and rigid elements consist of thin, flat braces interlinked flexibly.

Advantageously, said elements capable of converting the solar energy into electrical energy may be flexible photovoltaic cells.

Advantageously, the flexible photovoltaic cells are made of AsGa.

Advantageously, said at least one tape-spring has a domed face and it is wound without preference with the domed face outward or the domed face inward.

### BRIEF DESCRIPTION OF THE DRAWINGS

Other features and advantages of the invention will become apparent from the following description given in light of the appended drawings which represent:

FIG. 1: a rigid solar generator in configuration stored in the nose cone of a launch vehicle and in deployed configuration, according to the prior art;

FIG. 2: an example of a device according to the invention, comprising solar generators with a membrane coated with photovoltaic cells, during deployment;

FIG. 3: the same example of a device according to the invention, but with double membranes and in deployed configuration;

FIG. 4: examples of nose-cone configuration of devices according to the invention, according to different embodiments.

### DETAILED DESCRIPTION

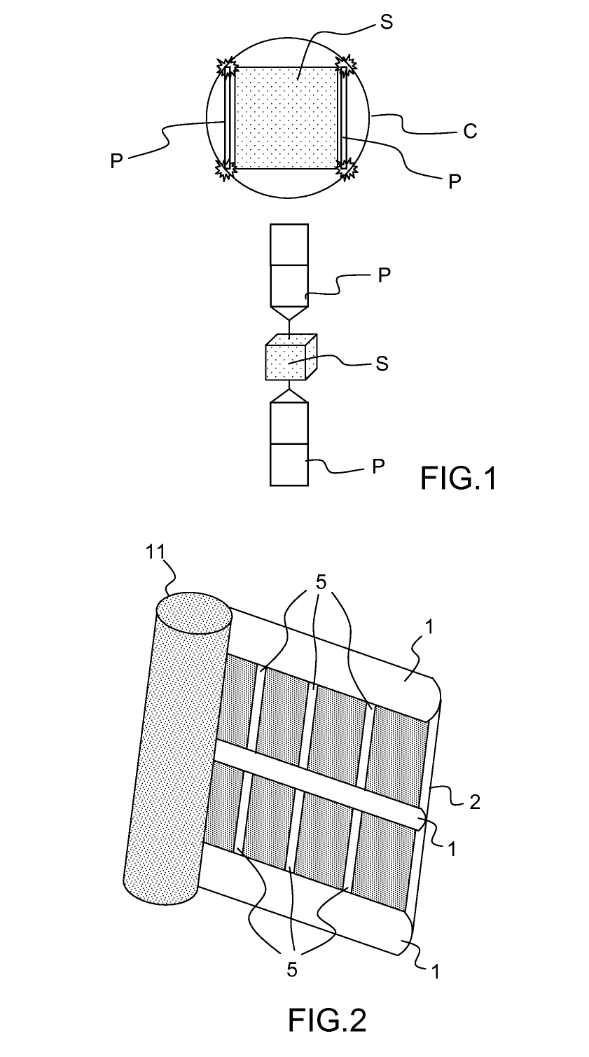

FIG. 1 shows a device example of known rigid solar panels P, intended to be deployed on either side of a body of a spacecraft S, in the configuration stored in the nose cone C of a launch vehicle and in deployed configuration. As stated previously, the rigid solar panels P form, in the nose cone C, a bulk that is significant and not optimized relative to the volume allotted in the nose cone C.

FIG. 2 shows a diagram of an example of a device according to the invention. The latter comprises a flexible membrane 2, supporting a plurality of photovoltaic cells, a plurality of tape-springs 1 constituting a bearing structure. Alternatively, said membrane 2 may be semi-rigid or composed of flexible and rigid elements such as thin, flat braces interlinked flexibly.

In the wound state, the tape-springs 1 are preferably wound around their natural radius of curvature. A mandrill 11 may be present, essentially to ensure the winding support function for the flexible membrane 2.

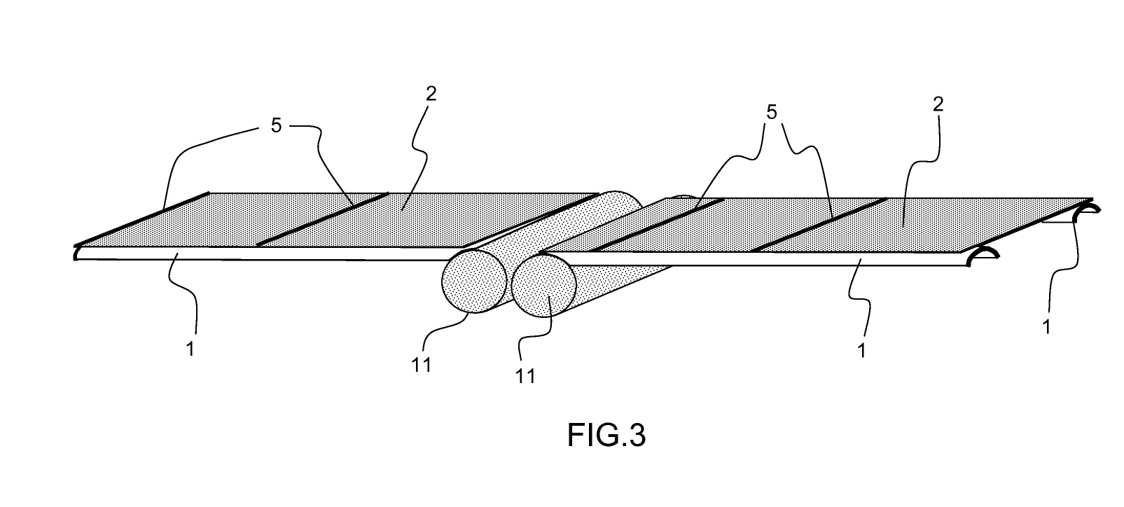

In the embodiment represented in FIGS. 2 and 3, two tape-springs 1 support the flexible membrane 2. Said tape-springs 1 are linked by transversal braces 5 in order to ensure the rigidity of the bearing structure of the flexible membrane 2. The tape-springs 1 may be positioned in different configurations depending on the stiffness requirement in the deployed configuration. The tape-springs 1 are preferentially wound with their domed face outward, as represented in FIG. 2, but it is also possible to have a winding with domed face inward. This is notably the usual practice for certain bistable tape-springs.

As represented in FIG. 3, in a more advanced state of deployment, the device according to the invention may comprise two similar, windable structures, the winding mandrills 11 of which are substantially parallel. Advantageously, the two structures can be deployed simultaneously through the intermediary of a rotation system for the mandrills 11 possibly combined with a system for reheating the tape-springs 1. In the deployed configuration, the two membranes can be mounted on the mandrill tangentially or radially, so as to be positioned in unique or parallel planes.

In the preferred embodiment of the invention, for the flexible membrane 2, the bearing structure consisting of a plurality of tape-springs 1 in fact comprises at least one main tape-spring and at least one conventional secondary tape-spring, made of metal or a composite material, the function of the secondary tape-springs being to provide motor-drive for the deployment of the membranes by virtue of their natural tendency to unfold and the functions of the main tape-springs being to maintain the membranes in the wound position before deployment and to regulate the deployment by means of actuations. These deployment systems can be coupled to a system enabling the mandrill 11 to rotate at the same time as the membrane(s) 2 are being deployed.

The at least one main tape-spring may combine a composite material and a layer of a material exhibiting a strong rigidity variation on crossing a temperature threshold, for example a thermoplastic material, and the actuation means are thermal.

Alternatively, the at least one main tape-spring may be of bistable type, the actuation means being locally acting triggering means, for example in the form of a mechanism which curves the flat section of the end of the tape-spring and thus triggers its unwinding.

Alternatively, the at least one main tape-spring may be of bistable type and comprise a layer of material exhibiting a strong rigidity variation on crossing a temperature threshold, the actuation means being thermal.

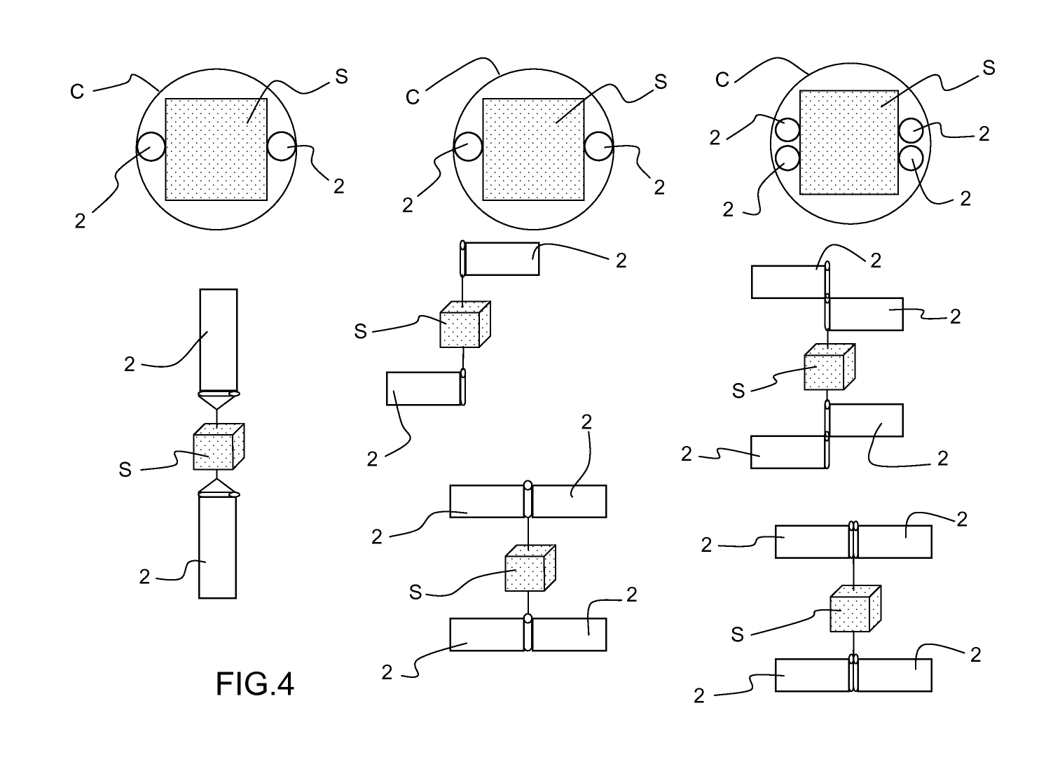

FIG. 4 illustrates different in-nose-cone and deployed configurations of solar generator deployment devices according to the invention. In the stored position, as the diagrams of FIG. 4 show, the wound state of the membranes 2 supported by a tape-spring bearing structure has little bulk.

To sum up, the invention offers the main advantage of proposing a solution for the deployment large size solar generators, using a simple, and above all compact, mechanism.

1. A solar generator deployment device, comprising:
an assembly comprising a plurality of tape-springs supporting a windable membrane on a face of which is arranged a plurality of elements capable of converting the solar energy into electrical energy,
wherein, in the wound state, said tape-springs and said membrane are co-wound around a unique radius of curvature equal to the natural radius of curvature of folding of the tape-spring; and
said tape-springs are substantially parallel and interlinked by transversal braces ensuring the rigidity of the bearing structure.

2. The device as claimed in claim 1, wherein said assembly comprises:
at least one main tape-spring, the function of which is to maintain the membrane in the wound position before deployment and to regulate the deployment using actuation means; and,
at least one conventional secondary tape-spring, made of metal or of composite material, the function of which is to provide motorization for the deployment of the membrane by its natural tendency to unfold.

3. The device as claimed in claim 2, wherein the at least one main tape-spring combines a composite material and a layer of a material exhibiting a strong rigidity variation on crossing a temperature threshold and the actuation means are thermal.

4. The device as claimed in claim 2, wherein the at least one main tape-spring combines a composite material and a thermoplastic layer and the actuation means are thermal.

5. The device as claimed in claim 2, wherein the at least one main tape-spring is of bistable type and the actuation means are triggering means.

6. The device as claimed in claim 2, wherein the at least one main tape-spring is of bistable type and also comprises a layer or a material exhibiting a strong rigidity variation on crossing a temperature threshold and the actuation means are thermal.

7. The device as claimed in claim 1, wherein said assembly and said membrane are co-wound around a mandrill.

8. The device as claimed in claim 1, wherein said elements capable of transforming the solar energy into electrical energy are flexible photovoltaic cells.

9. The device as claimed in claim 8, wherein said flexible photovoltaic cells are made of AsGa.

10. The device as claimed in claim 1, wherein said membrane is flexible.

11. The device as claimed in claim 1, wherein said membrane is made up of flexible and rigid elements.

12. The device as claimed in claim 11, wherein said flexible and rigid elements consist of thin, flat braces interlinked flexibly.

13. The device as claimed in claim 1, wherein said tape-springs have a domed face and are wound without preference with the domed face outward or the domed face inward.
